(19) United States
(12) Patent Application Publication
(10) Pub. No.: US 2026/0223752 A1
(43) Pub. Date: Jul. 30, 2026

(54) SEMICONDUCTOR CHIP AND METHOD OF MANUFACTURING SEMICONDUCTOR CHIP

(71) Applicant: Samsung Electronics Co., Ltd., Suwon-si (KR)

(72) Inventor: Geming WU, Suzhou (CN)

(73) Assignee: Samsung Electronics Co., Ltd., Suwon-si (KR)

(21) Appl. No.: 19/183,161

(22) Filed: Apr. 18, 2025

(30) Foreign Application Priority Data
Jan. 24, 2025 (CN) 202510114751.4

(51) Int. Cl. H10W 90/00; H10P 58/00; H10W 72/20; H10W 74/10; H10W 90/26

(52) U.S. Cl. CPC H10W 90/724; H10W 72/248; H10W 90/26; H10W 90/722; H10P 58/00; H10W 74/117

(57) ABSTRACT

A semiconductor chip and a method of manufacturing a semiconductor chip are provided. The semiconductor chip may include a chip substrate, a pattern on an upper surface of the chip substrate, a scribe lane on the upper surface of the chip substrate and surrounding the pattern, and a chip redistribution layer in the pattern, the chip redistribution layer extending from the pattern into the scribe lane, passing through the scribe lane, and exposed to an outside of the scribe lane. According to an example embodiment of the present disclosure, because the chip redistribution layer is exposed to the outside of the scribe lane and an outer side surface of the scribe lane is coplanar with a side surface of the chip substrate, electrical connection between the semiconductor chip and an external device can be implemented at a side surface of the semiconductor chip.

### CROSS-REFERENCE TO RELATED APPLICATIONS

This application claims priority under 35 U.S.C. § 119 to Chinese Patent Application No. 202510114751.4, filed on Jan. 24, 2025, in the State Intellectual Property Office of the P.R.C., the disclosure of which is incorporated herein in their entirety by reference.

### BACKGROUND

### Field

Some example embodiments of the present inventive concepts relate to the field of semiconductor packaging, and more particularly, relate to semiconductor chips and/or methods of manufacturing a semiconductor chip.

### Description of the Related Art

In a semiconductor package, electrical connection between a semiconductor chip and one surface of a substrate is implemented by using a manner of lead bonding, and the semiconductor package is formed through sealing of a molding compound to protect the semiconductor chip and a circuit. Balls are planted on another surface of the substrate and finally the semiconductor package is soldered to a circuit board of a terminal product through a surface mount technology (SMT) process, thereby implementing electrical connection between the semiconductor chip and the external device.

However, as the demand for miniaturized and higher-performance semiconductor chips continues to increase, the miniaturized and higher-performance semiconductor chips with a thinner thickness, a larger bandwidth, and a larger number of input and output (IO) are being studied.

### SUMMARY

Some example embodiments of the present inventive concepts provide miniaturized and higher-performance semiconductor chips having a thinner thickness, a larger bandwidth, and a larger number of input and output (IO), and/or methods of manufacturing a semiconductor chip.

According to an example embodiment of the present inventive concepts, a semiconductor chip may include a chip substrate, a pattern on an upper surface of the chip substrate, a scribe lane on the upper surface of the chip substrate and surrounding the pattern, and a chip redistribution layer in the pattern, the chip redistribution layer extending from the pattern into the scribe lane, passing through the scribe lane, and exposed to an outside of the scribe lane.

In some example embodiments, the pattern may cover a portion of the upper surface of the chip substrate, and the scribe lane may cover a remaining portion of the upper surface of the chip substrate.

In some example embodiments, an inner side surface of the scribe lane may contact the pattern, and an outer side surface of the scribe lane may be coplanar with a side surface of the chip substrate.

In some example embodiments, the chip redistribution layer may extend from the pattern into the scribe lane in a direction parallel to the upper surface of the chip substrate.

In some example embodiments, an exposed surface of the chip redistribution layer exposed to the outside of the scribe lane may be coplanar with an outer side surface of the scribe lane.

In some example embodiments, the semiconductor chip may be included in a semiconductor package.

In some example embodiments, the semiconductor chip may further include a through mold via extending along the outer side surface of the scribe lane and a side surface of the chip substrate and electrically connected to the exposed surfaces of the chip redistribution layer.

In some example embodiments, the semiconductor chip may further include a chip mold layer covering an upper surface of the pattern, an upper surface of the scribe lane and an outer side surface of the through mold via, wherein the through mold via passes through the chip mold layer to be exposed to an outside of both a first surface as an active surface and a second surface, the second surface of the semiconductor chip being opposite to the first surface of the semiconductor chip.

In some example embodiments, the semiconductor package may include a package substrate including a first surface and a second surface opposite to the first surface, wherein an active surface of the semiconductor chip faces upward on the first surface of the package substrate, and the chip redistribution layer of the semiconductor chip is electrically connected to the package substrate through the through mold via, a package mold layer on the first surface of the package substrate and covering the semiconductor chip, and an external connection terminal on the second surface of the package substrate.

In some example embodiments, the semiconductor package may include: a package redistribution layer including the first surface and the second surface opposite to the first surface, wherein the active surface of the semiconductor chip facies downward on the first surface of the package redistribution layer, and the chip redistribution layer of the semiconductor chip is electrically connected to the package redistribution layer through the through mold via, and a package mold layer on the first surface of the package redistribution layer and covering the semiconductor chip, and an external connection terminal on the second surface of the package redistribution layer.

In some example embodiments, the semiconductor package may include: a package redistribution layer including a first surface and a second surface opposite to the first surface, wherein an active surface of the semiconductor chip faces downward on the first surface of the package redistribution layer, and the chip redistribution layer of the semiconductor chip is electrically connected to the package redistribution layer through the through mold via, and an external connection terminal on the second surface of the package redistribution layer.

In some example embodiments, the semiconductor chip may be a first semiconductor chip, the semiconductor package may further include a second semiconductor chip vertically stacked on the first semiconductor chip, and the first semiconductor chip and the second semiconductor chip may be electrically connected to each other through the through mold via.

According to an example embodiment of the present inventive concepts, a method of manufacturing a semiconductor chip may include forming a plurality of patterns, a plurality of scribe lanes, and a plurality of chip redistribution layers on a semiconductor mother substrate such that the plurality of patterns are spaced apart by the plurality of scribe lanes, and the plurality of chip redistribution layers extend from corresponding ones of the plurality of patterns into corresponding ones of the plurality of scribe lanes, respectively, performing a first scribing operation on the semiconductor mother substrate along the plurality of scribe lanes to form a first groove in each of the plurality of scribe lanes, the first groove extending into the semiconductor mother substrate and having a first depth and a first width such that each of the plurality of chip redistribution layers is exposed through the first groove, performing a first molding operation to form a chip mold layer filling the first groove, forming holes through the chip mold layer along an inner side surface of the filled first groove to expose each of the plurality of chip redistribution layers through the holes, filling the holes with a conductive material to form a plurality of through mold vias that is electrically connected to the plurality of chip redistribution layers, respectively; and performing a second scribing operation on the semiconductor mother substrate along the filled first groove to form a plurality of semiconductor chips each including the plurality of patterns.

In some example embodiments, the plurality of scribe lanes may include a plurality of first scribe lanes extending in a first direction and a plurality of second scribe lanes extending in a second direction intersecting the first direction.

In some example embodiments, each of the plurality of patterns may be spaced apart from adjacent ones of the plurality of patterns through two of the plurality of first scribe lanes and two of the plurality of second scribe lanes.

In some example embodiments, the plurality of chip redistribution layers may include a plurality of first chip redistribution layers each extending from a corresponding one of the plurality of patterns into a corresponding one of the plurality of first scribe lanes and a plurality of second chip redistribution layers each extending from a corresponding one of the plurality of patterns into a corresponding one of the plurality of second scribe lanes.

In some example embodiments, the first depth may be greater than a depth of each of the plurality of scribe lanes, and the first width may be less than a width of each of the plurality of scribe lanes.

In some example embodiments, each of the plurality of patterns may be spaced apart from the first groove by a portion that is not scribed in each of the plurality of scribe lanes.

In some example embodiments, the performing the first molding operation may further include forming the chip mold layer to cover upper surfaces of the plurality of patterns and upper surfaces of portions that are not scribed in the plurality of scribe lanes.

In some example embodiments, the forming the holes may include forming the holes on opposite inner side surfaces of the first groove in a cross-sectional view and expose the chip redistribution layers facing each other across the first groove, respectively.

In some example embodiments, the performing the second scribing operation includes performing a thinning operation on the semiconductor mother substrate to expose the plurality of through mold vias, disposing the thinned semiconductor mother substrate on a first carrier plate, and performing the second scribing operation to form a second groove having a second width in the filled first groove, such that the plurality of semiconductor chips are spaced apart from each other by the second groove.

In some example embodiments, the second width may be less than the first width, and the second groove may not extend into the first carrier plate.

In some example embodiments, the first carrier plate may include a transparent carrier plate and a photosensitive sticky film on the transparent carrier plate, and the semiconductor mother substrate may be adhered to the photosensitive sticky film.

In some example embodiments, after the performing the second scribing, the method may further include picking up and mounting the plurality of semiconductor chips from the first carrier plate onto a first surface of a package substrate, performing a second molding operation to form a package mold layer covering the plurality of semiconductor chips on the first surface of the package substrate, forming the external connection terminal on the second surface of the package substrate opposite to the first surface, and performing a third scribing operation to form a plurality of semiconductor packages each including the plurality of semiconductor chips.

In some example embodiments, the picking up and mounting may include forming a plurality of semiconductor chip stacks spaced apart from each other on the first surface of the package substrate, and the performing the third scribing operation may form a plurality of semiconductor packages each including the plurality of semiconductor chip stacks.

In some example embodiments, after the filling the holes with the conductive material, the method further includes performing a thinning operation on the semiconductor mother substrate to expose the plurality of through mold vias and obtain a first semiconductor mother substrate, vertically stacking a second semiconductor mother substrate that is identical to the first semiconductor mother substrate on the first semiconductor mother substrate such that the first semiconductor mother substrate and the second semiconductor mother substrate are electrically connected to each other through respective through corresponding ones of the plurality of mold vias to form a semiconductor mother substrate bond, and disposing the semiconductor mother substrate bond on a first carrier plate.

In some example embodiments, the method may further include performing the second scribing operation on the semiconductor mother substrate bond along the filled first groove of each of the first semiconductor mother substrate and the second semiconductor mother substrate to form a plurality of semiconductor chip stacks spaced apart from each other, picking up and mounting the plurality of semiconductor chip stacks from the first carrier plate onto a first surface of a package substrate, performing a second molding operation to form a package mold layer covering the plurality of semiconductor chip stacks on the first surface of the package substrate, forming an external connection terminal on a second surface of the package substrate opposite to the first surface, and performing a third scribing operation to form a plurality of semiconductor packages each including the plurality of semiconductor chip stacks.

In some example embodiments, the method may further include performing the second scribing operation on the semiconductor mother substrate bond along the filled first groove of each of the first semiconductor mother substrate and the second semiconductor mother substrate to form a plurality of semiconductor chip stacks spaced apart from each other, picking up and mounting the plurality of semiconductor chip stacks from the first carrier plate onto a first surface of a second carrier plate, performing a second molding operation to form a package mold layer covering the plurality of semiconductor chip stacks on the first surface of the second carrier plate, removing the second carrier plate to expose the plurality of semiconductor chip stacks, forming a package redistribution layer on an exposed surface of the plurality of semiconductor chip stacks, forming the external connection terminal on the package redistribution layer, and performing a third scribing operation to form a plurality of semiconductor packages each including the plurality of semiconductor chip stacks.

In some example embodiments, the method may further include forming a package redistribution layer on a second surface of the semiconductor mother substrate bond opposite to a first surface of the semiconductor mother substrate bond that is mounted onto the first carrier plate, forming an external connection terminal on the package redistribution layer, removing the first carrier plate to expose the first surface of the semiconductor mother substrate bond, forming a protection layer on the first surface of the semiconductor mother substrate bond, and performing the second scribing operation on the semiconductor mother substrate bond along the filled first groove of each of the first semiconductor mother substrate and the second semiconductor mother substrate to form a plurality of semiconductor packages each including a plurality of semiconductor chip stacks.

According to some example embodiments of the present disclosure, because the chip redistribution layer is exposed to the outside of the scribe lane and an outer side surface of the scribe lane is coplanar with a side surface of the chip substrate, electrical connection between the semiconductor chip and an external device can be implemented at a side surface of the semiconductor chip, so that a thickness of a package including the semiconductor chip may be reduced, and bandwidths and the number of input and output (IO) of the semiconductor chip also may be increased to improve performance.

### BRIEF DESCRIPTION OF THE DRAWINGS

The above and/or other aspects of the present inventive concepts will become apparent and more readily understood from the following detailed descriptions taken in conjunction with the accompanying drawings.

FIG. 1 is a diagram illustrating a semiconductor chip according to an example embodiment of the present disclosure.

FIGS. 2A and 2B are diagrams illustrating a semiconductor chip according to an example embodiment of the present disclosure.

FIG. 3 is a diagram illustrating a semiconductor package according to an example embodiment of the present disclosure.

FIG. 4 is a diagram illustrating a semiconductor package according to an example embodiment of the present disclosure.

FIG. 5 is a diagram illustrating a semiconductor package according to an example embodiment of the present disclosure.

FIG. 6 is a flowchart illustrating a method of manufacturing a semiconductor chip according to an example embodiment of the present disclosure.

FIGS. 7A-7C are process diagrams illustrating the method of FIG. 6 according to an example embodiment of the present disclosure.

FIG. 8 is a flowchart illustrating intermediate steps of a method of manufacturing a semiconductor chip according to an example embodiment of the present disclosure.

FIG. 9 is a flowchart illustrating a method of manufacturing a package of the semiconductor chip according to an example embodiment of the present disclosure.

FIG. 10 is a flowchart illustrating the method of manufacturing the semiconductor chip according to an example embodiment of the present disclosure.

FIG. 11 is a process diagram illustrating the methods of FIGS. 10 and 12 according to an example embodiment of the present disclosure.

FIG. 12 is a flowchart illustrating the method of manufacturing a package of the semiconductor chip according to an example embodiment of the present disclosure.

FIG. 13 is a flowchart illustrating the method of manufacturing a package of the semiconductor chip according to an example embodiment of the present disclosure.

FIG. 14 is a process diagram illustrating the method of FIG. 13 according to an example embodiment of the present disclosure.

FIG. 15 is a flowchart illustrating the methods of manufacturing the semiconductor chip and the package thereof according to an example embodiment of the present disclosure.

FIG. 16 is a process diagram illustrating the method of FIG. 15 according to an example embodiment of the present disclosure.

Throughout the drawings and specific example embodiments, like reference numerals will be understood to denote like elements, features, and structures unless otherwise described or provided. The drawings may not be to scale, and the relative dimensions, scales, and depictions of elements in the drawings may be exaggerated for clarity, illustration, and convenience.

### DETAILED DESCRIPTION

Hereinafter, some example embodiments of the present disclosure will be described in detail with reference to the accompanying drawings so that those skilled in the art may easily practice the inventive concepts. However, the inventive concepts may be implemented in various different forms and is not limited to the example embodiments described herein.

In the drawings, like numbers refer to like components throughout. Though the different figures show various example embodiments, these figures are not necessarily intended to be mutually exclusive from each other. Rather, as will be seen from the context of the detailed description below, certain features depicted and described in different figures can be combined with other features from other figures to result in various example embodiments, when taking the figures and their description as a whole into consideration. In the description of the drawing, components that are the same or similar in multiple drawings may not be described or may be only briefly referenced when the same or similar component was described in reference to an earlier drawing.

In addition, the size and thickness of each component shown in the accompanying drawings are arbitrarily shown for convenience of explanation, and therefore, the inventive concepts are not necessarily limited to contents shown in the drawings. The thicknesses are exaggerated in the drawings in order to clearly represent several layers and regions. In addition, the thicknesses of some layers and regions are exaggerated in the drawings for convenience of explanation.

In addition, when an element such as a layer, a film, a region or a substrate is referred to as being “on” or “above” another element, the element may be “directly on” another element or may have other elements interposed therebetween. On the other hand, when an element is referred to as being “directly on” another element, there is no third element or other elements interposed therebetween. In addition, when an element is referred to as being “on” or “above” a reference element, the element may be disposed below the reference element when the example embodiment is rotated to a different orientation than shown in the figures. As such, the use of the term above may not be in reference to a gravitational direction but may instead be specific to the drawing being described, and may not necessarily be “on” or “above” the reference element in an opposite direction of gravity.

In addition, throughout the specification, when an element “includes” another component, it is to be understood that the element may further include a third component rather than excluding the third component, unless explicitly described to the contrary. As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”.

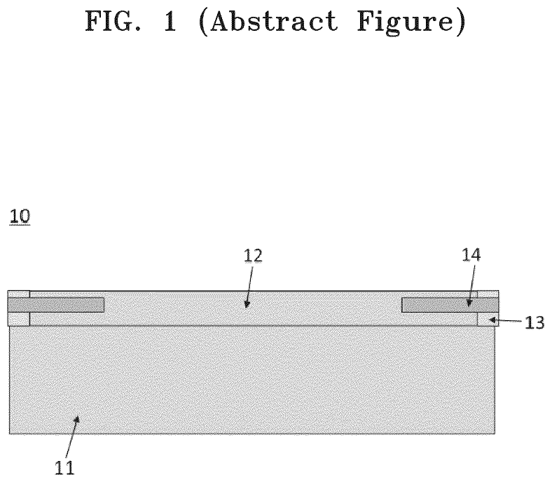

FIG. 1 is a diagram illustrating a semiconductor chip 10 according to an example embodiment of the present disclosure.

Referring to FIG. 1, the semiconductor chip 10 may include a chip substrate 11, a pattern 12, a scribe lane 13 and a chip redistribution layer (RDL) 14.

The chip substrate 11 may include a semiconductor material, such as a group IV semiconductor, a group III-V compound semiconductor, or a group II-VI compound semiconductor. For example, a group IV semiconductor may include silicon, germanium, or silicon-germanium. The chip substrate 11 may be configured as a silicon substrate, silicon-on-insulator (SOI) substrate, germanium substrate, germanium-on-insulator (GOI) substrate, silicon-germanium substrate, or a substrate including an epitaxial layer. The chip substrate 111 may include an upper surface and a lower surface opposite to each other in a vertical direction.

The pattern 12 may be disposed on an upper surface of the chip substrate 11. For example, the pattern 12 may be configured to extend in parallel on the upper surface of the chip substrate 11. In one example embodiment, the pattern 12 may cover a portion of the upper surface of the chip substrate 11. For example, the pattern 12 may be configured to extend in parallel on a central portion of the upper surface of the chip substrate 11 and cover the central portion of the upper surface of the chip substrate 11. The pattern 12 may be configured to implement functions of the semiconductor chip 10, and may be formed by performing a patterning process on the upper surface of the chip substrate 11. It should be understood that the functions of the semiconductor chip 10 implemented by the pattern 12 may include any function, which is not limited in the example embodiments of the present disclosure.

The scribe lane 13 may be disposed on the upper surface of the chip substrate 11, may be located at an edge of the upper surface of the chip substrate 11, and may surround the pattern 12. For example, the scribe lane 13 may be configured to be spaced apart from the upper surface of the chip substrate 11, extend in parallel above the upper surface of the chip substrate 11, and surround at least a portion of a side surface of the pattern 12. In one example embodiment, the scribe lane 13 may cover a remaining portion of the upper surface of the chip substrate 11. For example, the scribe lane 13 may be configured to extend in parallel on a portion of the upper surface of the chip substrate 11 that is not covered by the pattern 12 (hereinafter, referred to as a peripheral portion), and may cover a peripheral portion of the upper surface of the chip substrate 11. In one example embodiment, an inner side surface of the scribe lane 13 may contact the pattern 12, and an outer side surface of the scribe lane 13 may be coplanar with a side surface of the chip substrate 11.

A chip redistribution layer 14 may be disposed in the pattern 12, extend from the pattern 12 into the scribe lane 13, and pass through the scribe lane 13 to be exposed to an outside of the scribe lane 13. The chip redistribution layer 14 may be a metal layer for redistributing electrical connections and may include a plurality of wiring layers and a plurality of vias. In one example embodiment, the chip redistribution layer 14 may extend from the pattern 12 into the scribe lane 13 in a direction parallel to the upper surface of the chip substrate 11. For example, the chip redistribution layer 14 may extend in parallel above the upper surface of the chip substrate 11 and be spaced apart from the upper surface of the chip substrate 11 by a desired (or alternatively, predetermined) distance and the pattern 12 is disposed between a lower surface of the chip redistribution layer 14 and the upper surface of the chip substrate 11. In one example embodiment, an exposed surface of the chip redistribution layer 14 exposed to the outside of the scribe lane 13 may be coplanar with the outer side surface of the scribe lane 13.

According to example embodiments of the present disclosure, because the chip redistribution layer 14 is exposed to the outside of the scribe lane 13 and an outer side surface of the scribe lane 13 is coplanar with the side surface of the chip substrate 11, electrical connection between the semiconductor chip 10 and an external device can be implemented at the side surface of the semiconductor chip 10, so that a thickness of a package including the semiconductor chip 10 may be reduced, and bandwidths and the number of input and output (IO) of the semiconductor chip 10 also may be increased to improve performance.

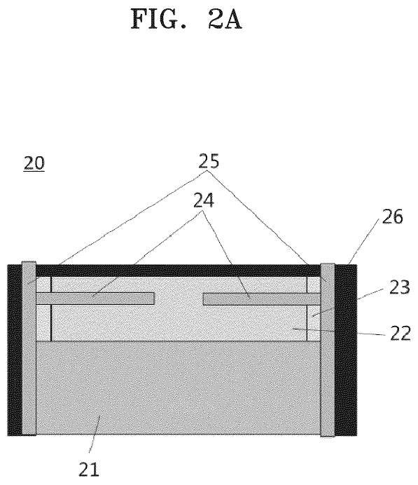

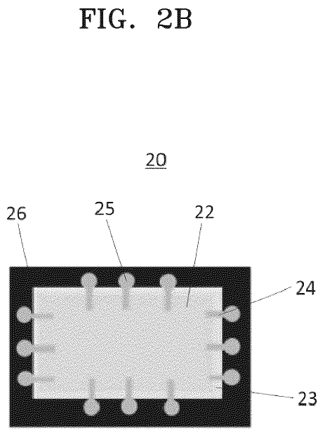

FIGS. 2A and 2B are diagrams illustrating a semiconductor chip 20 according to an example embodiment of the present disclosure.

Referring to FIGS. 2A and 2B, the semiconductor chip 20 may include a chip substrate 21, a pattern 22, a scribe lane 23, a chip redistribution layer 24, a through mold via (TMV) 25 and a chip mold layer 26. Except for the TMV 25 and the chip mold layer 26, the chip substrate 21, the pattern 22, the scribe lane 23, and the chip redistribution layer 24 of the semiconductor chip 20 described referring to FIGS. 2A and 2B may be the same as or substantially similar to the chip substrate 11, the pattern 12, the scribe lane 13, and the chip redistribution layer 14 of the semiconductor chip 10 described referring to FIG. 1, respectively. Thus, repeated descriptions thereof will be omitted.

Referring to FIG. 2A, the through mold via 25 may extend along an outer side surface of the scribe lane 23 and a side surface of the chip substrate 21 and may be electrically connected to exposed surfaces of the chip redistribution layer 24. The chip mold layer 26 may cover an upper surface of the pattern 22, an upper surface of the scribe lane 23 and an outer side surface of the through mold via 25. In one example, the chip mold layer 26 may include, but is not limited to, for example, an epoxy molding compound (EMC). In one example embodiment, the through mold via 25 may pass through the chip mold layer 26 to be exposed to an outside of both a first surface, which is an active surface, and a second surface. The second surface of the semiconductor chip 20 is opposite to the first surface of the semiconductor chip 20.

Referring to FIG. 2B, the through mold vias 25 may be arranged in a plurality along a periphery of the scribe lane 23. When viewed in a plan view, the scribe lane 23 may have a same shape as the chip substrate 21. For example, the scribe lane 23 may have a rectangular shape extending along a peripheral portion of the chip substrate 21. The through mold via 25 may be arranged at a uniform interval along each side of the rectangular shape. For example, three through mold vias 25 may be arranged on each side of the rectangular shape. However, the example embodiment of the present disclosure is not limited thereto.

According to the example embodiment of the present disclosure, because the chip redistribution layer 24 is electrically connected to the through mold via 25 extending along the outer side surface of the scribe lane 23 and the side surface of the chip substrate 21, electrical connection between the semiconductor chip 20 and an external device can be implemented at a side surface of the semiconductor chip 20, so that a thickness of a package including the semiconductor chip 20 may be reduced, and bandwidths and the number of input and output (IO) of the semiconductor chip 20 also may be increased to improve performance.

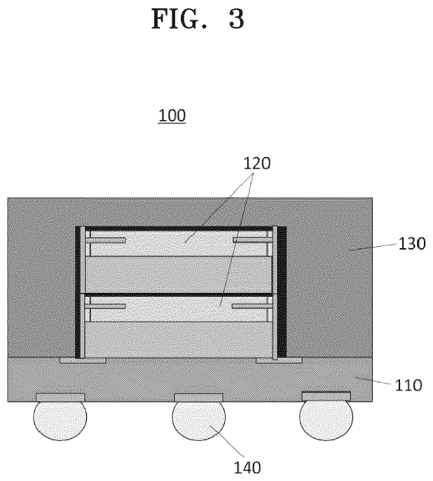

FIG. 3 is a diagram illustrating a semiconductor package 100 according to an example embodiment of the present disclosure.

Referring to FIG. 3, the semiconductor chip 100 may include a package substrate 110, a semiconductor chip 120, a package mold layer 130, and an external connection terminal 140.

The package substrate 110 may include a first surface and a second surface opposite to the first surface. In one example, the package substrate 110 may be a multi-layer printed circuit board. A first surface and a second surface of the package substrate 110 may be provided with conductive contacts, and a conductive contact on the first surface of the package substrate 110 may be electrically connected to a conductive contact on the second surface of the package substrate 110.

The semiconductor chip 120 may be included in the semiconductor package 100. The semiconductor chip 120 may have an active surface disposed or facing upward on the first surface of the package substrate 110. The semiconductor chip 120 may be, for example, the semiconductor chip 10 described referring to FIG. 1 or the semiconductor chip 20 described referring to FIGS. 2A and 2B. A chip redistribution layer of the semiconductor chip 120 may be electrically connected to the package substrate 110 through the through mold via. For example, the chip redistribution layer of the semiconductor chip 120 may be electrically connected to the conductive contact on the first surface of the package substrate 110 through the through mold via.

In one example embodiment, the semiconductor package 100 may include one semiconductor chip (e.g., the semiconductor chip 120). In another example, the semiconductor chips 120 may include a first semiconductor chip and a second semiconductor chip. The second semiconductor chip may be vertically stacked on the first semiconductor chip, and the first semiconductor chip and the second semiconductor chip may be electrically connected to each other through corresponding through mold vias. However, the example embodiment of the present disclosure is not limited thereto. For example, the semiconductor package 100 may include three or more semiconductor chips.

The package mold layer 130 may be on the first surface of the package substrate 110 and cover the semiconductor chip 120. In one example, the package mold layer 130 and the chip mold layer of the semiconductor chip 120 may include the same or different materials.

The external connection terminal 140 may be disposed on the second surface of the package substrate 110. For example, the external connection terminal 140 may be disposed on the conductive contact on the second surface of the package substrate 110, and may be electrically connected to the through mold via of the semiconductor chip 120 disposed on the conductive contact on the first surface of the package substrate 110 through the conductive contact on the second surface of the package substrate 110. In one example, the external connection terminal 140 may include a pin in a form of a solder ball.

According to the example embodiment of the present disclosure, because the chip redistribution layer of the semiconductor chip is electrically connected to the through mold via extending along the outer side surface of the scribe lane and the side surface of the chip substrate, and is electrically connected to an external device through the package substrate 110, electrical connection between the semiconductor chip and the external device can be implemented at a side surface of the semiconductor chip, so that a thickness of the semiconductor package 100 may be reduced, and bandwidths and the number of input and output (IO) of the semiconductor chip 100 also may be increased to improve performance.

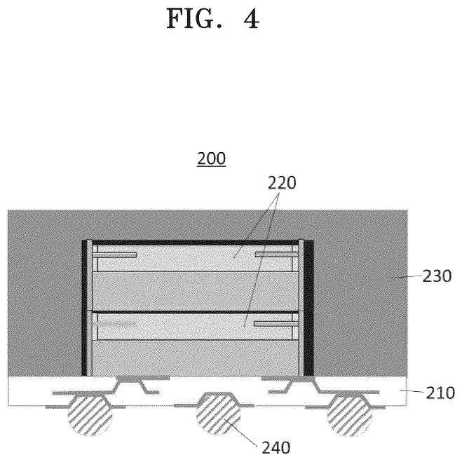

FIG. 4 is a diagram illustrating a semiconductor package 200 according to an example embodiment of the present disclosure.

Referring to FIG. 4, the semiconductor chip 200 may include a package redistribution layer 210, a semiconductor chip 220, a package mold layer 230, and an external connection terminal 240. Except for the package redistribution layer 210, the semiconductor chip 220, the package mold layer 230, and the external connection terminal 240 described referring to FIG. 4 may be substantially the same as or similar to the semiconductor chip 120, the package mold layer 130, and the external connection terminal 140 described referring to FIG. 3, respectively. Thus, repeated descriptions thereof will be omitted.

The package redistribution layer 210 may include a first surface and a second surface opposite to the first surface. In one example, the package redistribution layer 210 may include a plurality of wiring layers at different heights and a plurality of vias that electrically connect the plurality of wiring layers to each other. The first surface and the second surface of the package redistribution layer 210 may be disposed with corresponding ones of the plurality of wiring layers, respectively, and a wiring layer on the first surface of the package redistribution layer 210 may be electrically connected to a wiring layer on the second surface of the package redistribution layer 210.

The semiconductor chip 220 may be included in the semiconductor package 200. The semiconductor chip 220 may have an active surface disposed or facing upward on the first surface of the package redistribution layer 210. The semiconductor chip 220 may be, for example, the semiconductor chip 10 described referring to FIG. 1 or the semiconductor chip 20 described referring to FIGS. 2A and 2B. The chip redistribution layer of the semiconductor chip 220 may be electrically connected to the package redistribution layer 210 through the through mold via. For example, the chip redistribution layer of the semiconductor chip 220 may be electrically connected to the wiring layer on the first surface of the package redistribution layer 210 through the through mold via.

In one example embodiment, the semiconductor package 200 may include one semiconductor chip (e.g., the semiconductor chip 220). In another example, the semiconductor chips 220 may include a first semiconductor chip and a second semiconductor chip. The second semiconductor chip may be vertically stacked on the first semiconductor chip, and the first semiconductor chip and the second semiconductor chip may be electrically connected to each other through corresponding through mold vias. However, the example embodiment of the present disclosure is not limited thereto. For example, the semiconductor package 100 may include three or more semiconductor chips.

The package mold layer 230 may be on the first surface of the package redistribution layer 210 and cover the semiconductor chip 220. In one example, the package mold layer 230 and the chip mold layer of the semiconductor chip 220 may include the same or different materials.

The external connection terminal may be disposed on the second surface of the package redistribution layer 210. For example, the external connection terminal 240 may be disposed on the wiring layer on the second surface of the package redistribution layer 210, and may be electrically connected to the through mold via of the semiconductor chip 220 disposed on the wiring layer on the first surface of the package redistribution layer 210 through the wiring layer on the second surface of the package redistribution layer 210. In one example, the external connection terminal 240 may include a pin in the form of a solder ball.

According to the example embodiment of the present disclosure, because the chip redistribution layer of the semiconductor chip is electrically connected to the through mold via extending along the outer side surface of the scribe lane and the side surface of the chip substrate and is electrically connected to an external device through the package redistribution layer 210, electrical connection between the semiconductor chip and the external device can be implemented at a side surface of the semiconductor chip, so that a thickness of the semiconductor package 200 may be reduced, and bandwidths and the number of IO of the semiconductor chip 200 also may be increased to improve performance.

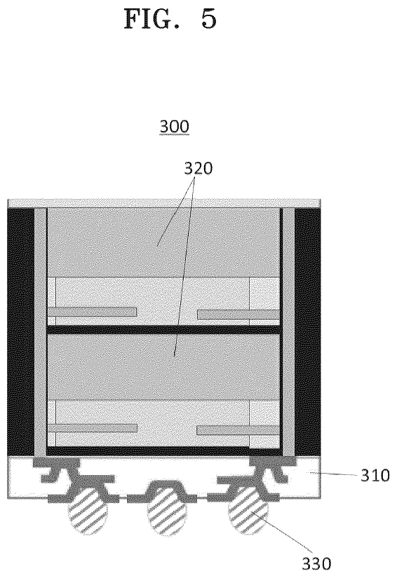

FIG. 5 is a diagram illustrating a semiconductor package 300 according to an example embodiment of the present disclosure.

Referring to FIG. 5, the semiconductor chip 300 may include a package redistribution layer 310, a semiconductor chip 320, a package mold layer, and an external connection terminal 330. Except for the semiconductor chip 320, the package redistribution layer 310, the package mold layer, and the external connection terminal 330 described referring to FIG. 5 may be the same as or substantially similar to the package redistribution layer 210, the package mold layer 230, and the external connection terminal 240 described referring to FIG. 4, respectively. Thus, repeated descriptions thereof will be omitted.

The semiconductor chip 320 may be included in the semiconductor package 300. Different from the semiconductor chip 220 described referring to FIG. 4, the semiconductor chip 320 may have an active surface disposed downward on a first surface of the package redistribution layer. The semiconductor chip 320 may be, for example, the semiconductor chip 10 described referring to FIG. 1 or the semiconductor chip 20 described referring to FIGS. 2A and 2B. The chip redistribution layer of the semiconductor chip 320 may be electrically connected to the package redistribution layer 310 through the through mold via. For example, the chip redistribution layer of the semiconductor chip 320 may be electrically connected to the wiring layer on the first surface of the package redistribution layer 310 through the through mold via.

In one example embodiment, the semiconductor package 300 may include one semiconductor chip (e.g., the semiconductor chip 320). In another example, the semiconductor chip 320 may include a first semiconductor chip and a second semiconductor chip. The second semiconductor chip may be vertically stacked on the first semiconductor chip, and the first semiconductor chip and the second semiconductor chip may be electrically connected to each other through corresponding through mold vias. However, example embodiment of the present disclosure is not limited thereto. For example, the semiconductor package 100 may include three or more semiconductor chips.

In one example embodiment, the semiconductor package 300 may further include a protection layer 340. The protection layer 340 may be disposed on the second surface (e.g., upper surface), which is an uppermost surface of the semiconductor chips 320.

According to the example embodiment of the present disclosure, because the chip redistribution layer of the semiconductor chip is electrically connected to the through mold via extending along the outer side surface of the scribe lane and the side surface of the chip substrate and is electrically connected to an external device through the package redistribution layer 310, electrical connection between the semiconductor chip and the external device can be implemented at a side surface of the semiconductor chip, so that a thickness of the semiconductor package 300 may be reduced, and bandwidths and the number of IO of the semiconductor chip 300 also may be increased to improve performance.

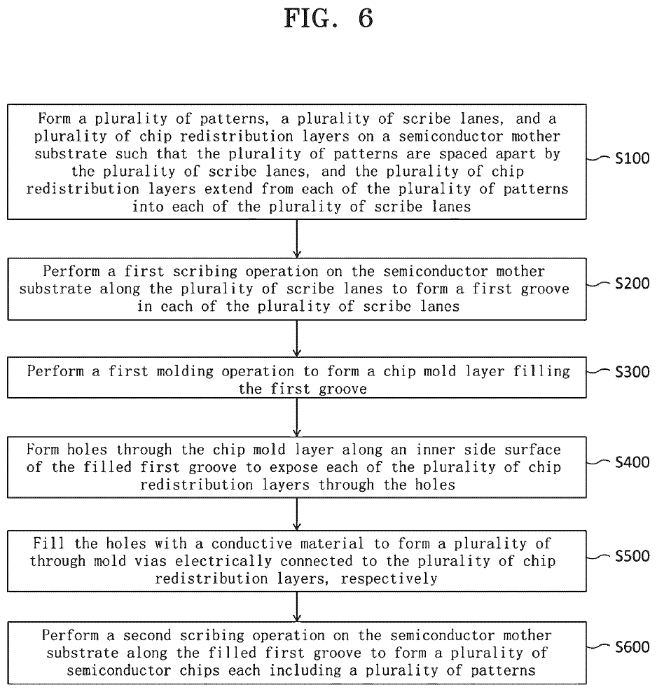

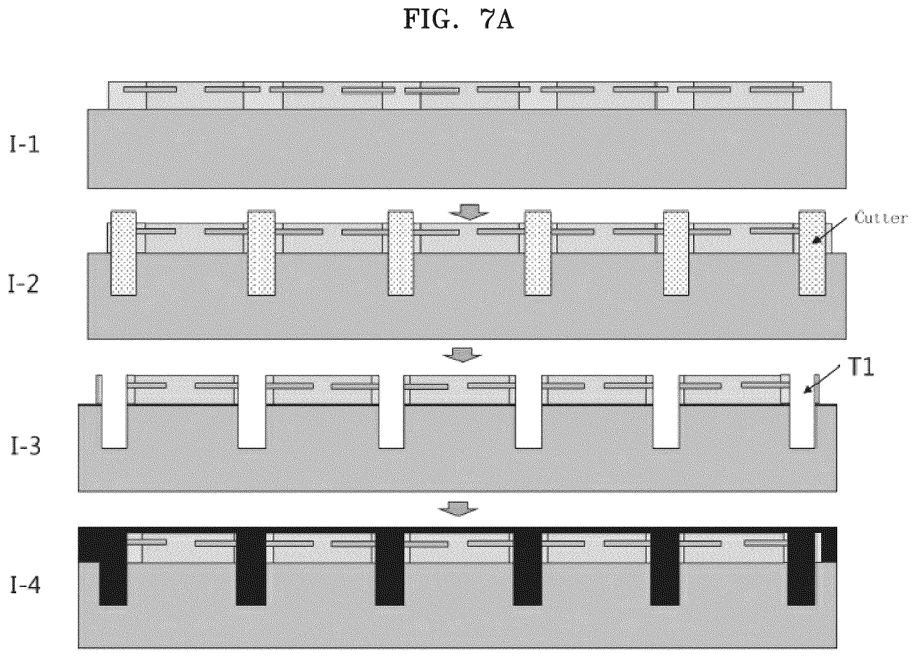

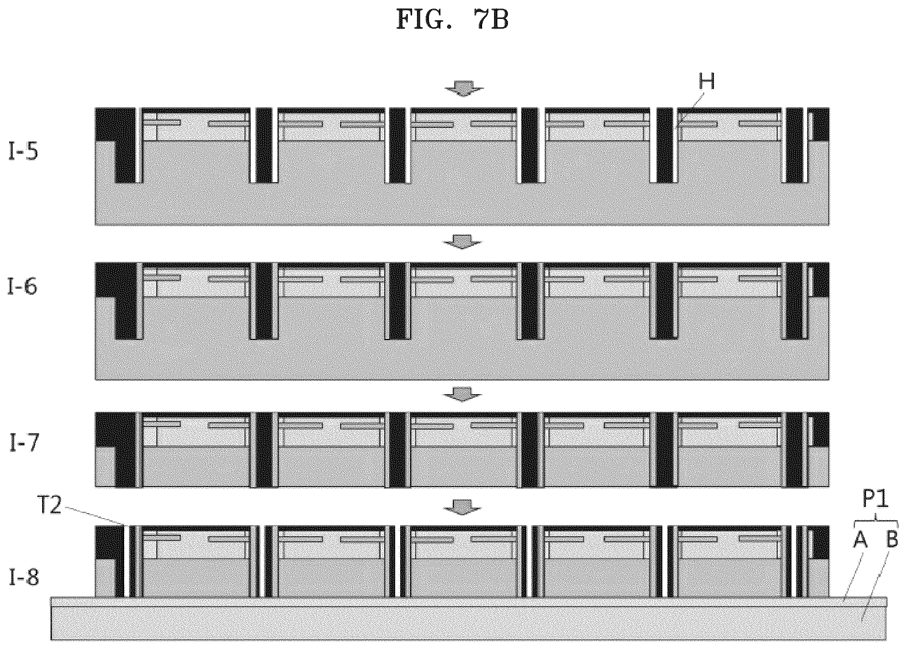

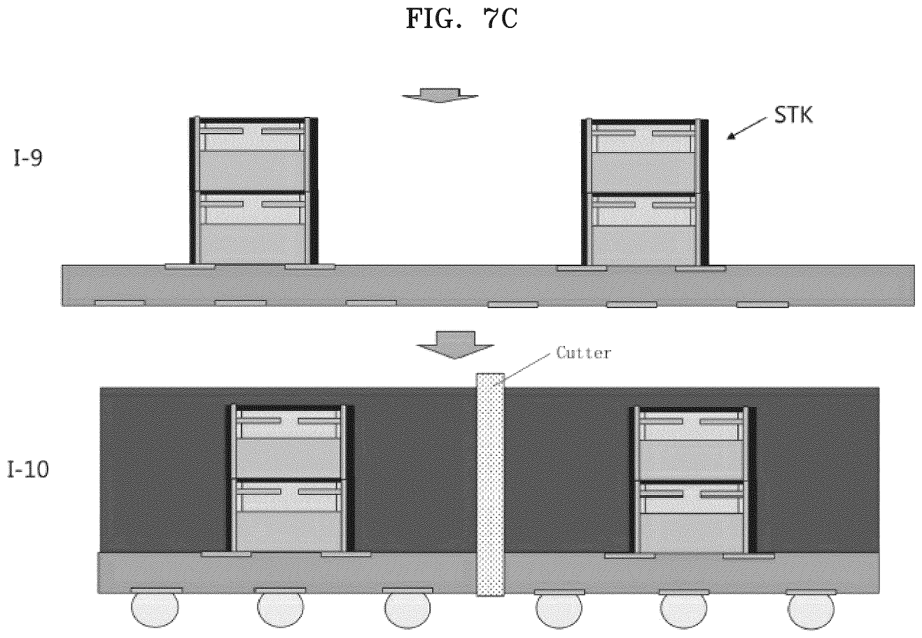

FIG. 6 is a flowchart illustrating the method of manufacturing the semiconductor chip according to an example embodiment of the present disclosure. FIGS. 7A-7C are process diagrams illustrating the method of FIG. 6 according to an example embodiment of the present disclosure.

Referring to FIGS. 6 and 7A-7C, taking the semiconductor package 100 shown in FIG. 3 as an example, the method of manufacturing the semiconductor chip may include steps S100 to S600.

In step S100 and process I-1, a plurality of patterns, a plurality of scribe lanes, and a plurality of chip redistribution layers respectively corresponding to a plurality of semiconductor chips may be formed on a semiconductor mother substrate such that the plurality of patterns may be spaced apart by the plurality of scribe lanes, and the plurality of chip redistribution layers may extend from corresponding ones of the plurality of patterns into corresponding ones of the plurality of scribe lanes, respectively. In one example, the semiconductor mother substrate described referring to FIGS. 6 and 7A-7C may be scribed or cut into individual semiconductor substrates each corresponding to one semiconductor chip after performing a scribing process (e.g., a sawing process), and this semiconductor substrate may be, for example, the chip substrate 11 described referring to FIG. 1 or the chip substrate 21 described referring to FIGS. 2A and 2B. In one example, the plurality of patterns described referring to FIGS. 6 and 7A-7C may include, for example, the pattern 12 described referring to FIG. 1 or the pattern 22 described referring to FIGS. 2A and 2B. In one example, the plurality of scribe lanes described referring to FIGS. 6 and 7A-7C may include, for example, the scribe lane 13 described referring to FIG. 1 or the scribe lane 23 described referring to FIGS. 2A and 2B. In one example, the plurality of chip redistribution layers described referring to FIGS. 6 and 7A-7C may include, for example, the chip redistribution layer 14 described referring to FIG. 1 or the chip redistribution layer 24 described referring to FIGS. 2A and 2B.

In one example embodiment, the plurality of scribe lanes may include a plurality of first scribe lanes extending in a first direction and a plurality of second scribe lanes extending in a second direction intersecting the first direction. The semiconductor mother substrate may be a wafer, for example, a 4-inch, 6-inch, 8-inch, or 12-inch silicon wafer. The first direction and the second direction may intersect in a plane parallel to an upper surface of the semiconductor mother substrate. In this case, in one example embodiment, each of the plurality of patterns may be spaced apart from an adjacent pattern of the plurality of patterns through two of the plurality of first scribe lanes and two of the plurality of second scribe lanes. In one example embodiment, the plurality of chip redistribution layers may include a plurality of first chip redistribution layers extending from each of the plurality of patterns into a corresponding one of the plurality of first scribe lanes and a plurality of second chip redistribution layers extending from each of the plurality of patterns into a corresponding one of the plurality of second scribe lanes.

In step S200 and processes I-2 and I-3, a first scribing operation may be performed on the semiconductor mother substrate along the plurality of scribe lanes to form a first groove T1 in each of the plurality of scribe lanes. The first groove T1 may extend into the semiconductor mother substrate and may have a first depth and a first width such that each of the plurality of chip redistribution layers may be exposed through the first groove T1. In one example embodiment, the first depth may be greater than a depth of each of the plurality of scribe lanes, and the first width may be less than a width of each of the plurality of scribe lanes. In one example embodiment, each of the plurality of patterns may be spaced apart from the first groove T1 by a portion that is not scribed in each of the plurality of scribe lanes.

In step S300 and process I-4, a first molding operation may be performed to form a chip mold layer filling the first groove T1. In one example, the chip mold layer described referring to FIGS. 6 and 7A-7C may be, for example, the chip mold layer 26 described referring to FIGS. 2A and 2B. In one example embodiment, the step S300 may include forming the chip mold layer to cover upper surfaces of the plurality of patterns and upper surfaces of portions that are not scribed in the plurality of scribe lanes.

In step S400 and process I-5, holes H through the chip mold layer is formed along an inner side surface of the filled first groove T1 to expose each of the plurality of chip redistribution layers through the holes H. In one example embodiment, the holes H may be formed on opposite inner side surfaces of the first groove T1 in a cross-sectional view and expose the chip redistribution layers facing each other across the first groove T1, respectively.

In step S500 and process I-6, the holes H may be filled with a conductive material to form a plurality of through mold vias electrically connected to the plurality of chip redistribution layers, respectively. In one example, the plurality of through mold vias described referring to FIGS. 6 and 7A-7C may include, for example, a through mold via 25 described referring to FIGS. 2A and 2B. In one example, the conductive material may include metal. In one example, the holes H may be filled through a deposition process.

In step S600 and processes I-7 to I-8, a second scribing operation may be performed on the semiconductor mother substrate along the filled first groove T1 to form a plurality of semiconductor chips each including the plurality of patterns. In one example, the formed plurality of semiconductor chips may include, for example, the semiconductor chip 10 described referring to FIG. 1 or the semiconductor chip 20 described referring to FIGS. 2A and 2B.

According to this example embodiment of the present disclosure, because the chip redistribution layer is exposed to the outside of the scribe lane and an outer side surface of the scribe lane is coplanar with a side surface of the chip substrate, electrical connection between the semiconductor chip and an external device can be realized at a side surface of the semiconductor chip, so that a thickness of a package including the semiconductor chip may be reduced, and bandwidths and the number of input and output (IO) of the semiconductor chip also may be increased to improve performance.

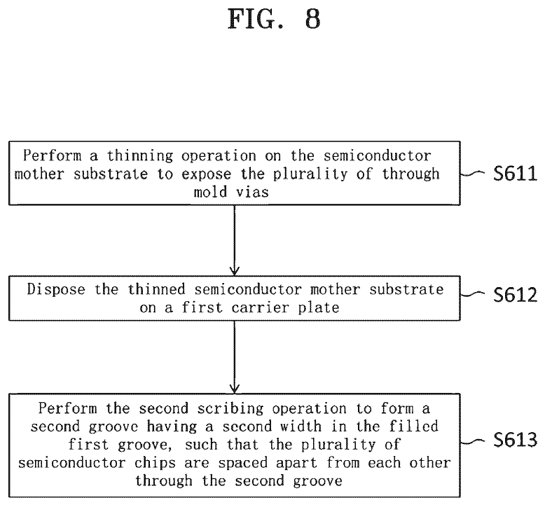

FIG. 8 is a flowchart illustrating intermediate steps of the method of manufacturing the semiconductor chip according to an example embodiment of the present disclosure.

Referring to FIGS. 7A-7C and 8 together with FIG. 6, in one example embodiment, the step S600 may include steps S611-S613.

In step 611 and process I-7, a thinning operation may be performed on the semiconductor mother substrate to expose the plurality of through mold vias. In step S612, the thinned semiconductor mother substrate may be disposed on a first carrier plate P1. In one example embodiment, the first carrier plate P1 may include a transparent carrier plate A and a photosensitive sticky film B positioned on the transparent carrier plate A, and the semiconductor mother substrate may be attached to the photosensitive sticky film B. In step S613 and process I-8, the second scribing operation may be performed to form a second groove T2 having a second width in the filled first groove T1 such that the plurality of semiconductor chips may be spaced apart from each other through the second groove T2. In one example embodiment, the second width may be less than the first width, and the second groove T2 may not extend into the first carrier plate P1. The second scribing operation may scribe or cut the semiconductor mother substrate into a plurality of semiconductor substrates to form a plurality of semiconductor chips.

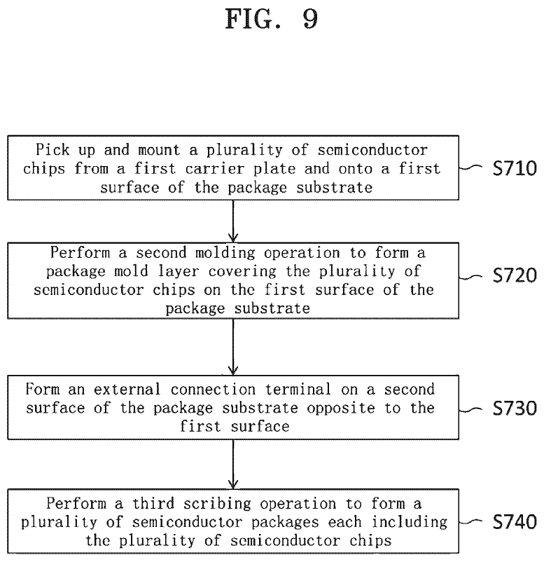

FIG. 9 is a flowchart illustrating the method of manufacturing the package of the semiconductor chip according to an example embodiment of the present disclosure.

Referring to FIGS. 7A-7C and 9 together with FIG. 6, in one example embodiment, after the step S613 shown in FIG. 8, steps S710-S740 may be performed.

In step S710 and process I-9, the plurality of semiconductor chips may be picked up from the first carrier plate P1 and mounted onto a first surface of a package substrate. In one example embodiment, the step S710 may include forming a plurality of semiconductor chip stacks STK spaced apart from each other on the first surface of the package substrate. In one example, each of the plurality of semiconductor chip stacks STK may include a plurality of semiconductor chips stacked on each other. Hereinafter, an example embodiments of forming the semiconductor chip stack STK will be described in detail referring to FIGS. 9-16.

In step S720 and process I-10, a second molding operation may be performed to form a package mold layer covering the plurality of semiconductor chips on the first surface of the package substrate. In one example, the package mold layer described referring to FIGS. 7A-7C and 9 may include, for example, the package mold layer 130 described referring to FIG. 3. In step S730 and process I-10, an external connection terminal may be formed on the second surface of the package substrate opposite to the first surface. In one example, the external connection terminal described referring to FIGS. 7A-7C and 9 may include, for example, the external connection terminal 140 described referring to FIG. 3. In step S740 and process I-10, a third scribing operation may be performed to form a plurality of semiconductor packages each including the plurality of semiconductor chips.

In one example, the plurality of semiconductor packages manufactured according to the flow chart of FIG. 9 may include, for example, the semiconductor package 100 shown in FIG. 3. According to the example embodiment of the present disclosure, because the chip redistribution layer is electrically connected to the through mold via extending along the outer side surface of the scribe lane and the side surface of the chip substrate, and is electrically connected to an external device through the package substrate 110, electrical connection between the semiconductor chip and the external device can be implemented at a side surface of the semiconductor chip, so that a thickness of the semiconductor package may be reduced, and bandwidths and the number of IO of the semiconductor chip also may be increased to improve performance.

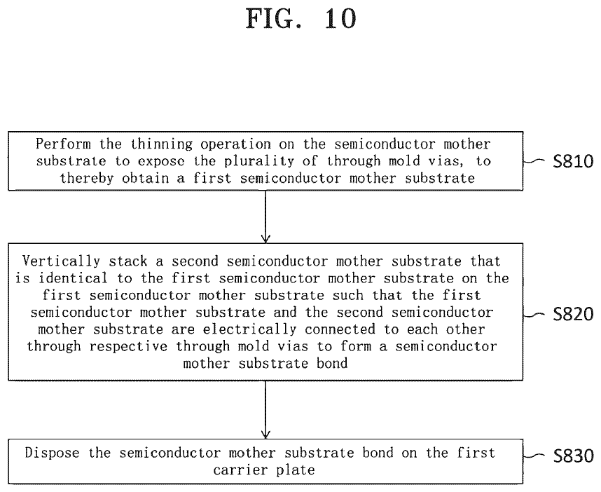

In one example embodiment, after performing the third scribing operation, a plurality of semiconductor packages each including a plurality of semiconductor chip stacks STK may be formed. Hereinafter, the example embodiments of forming a semiconductor chip package including a plurality of semiconductor chip stacks STK will be described in detail referring to FIGS. 10-16.

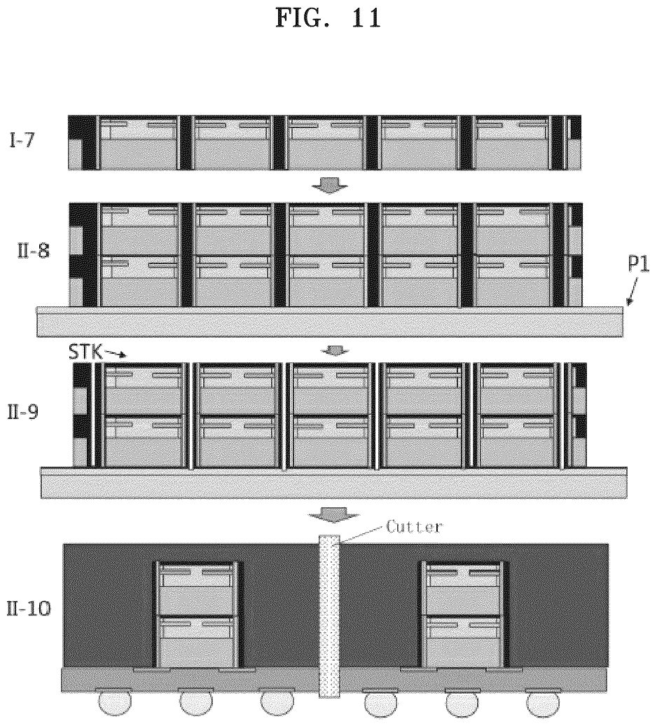

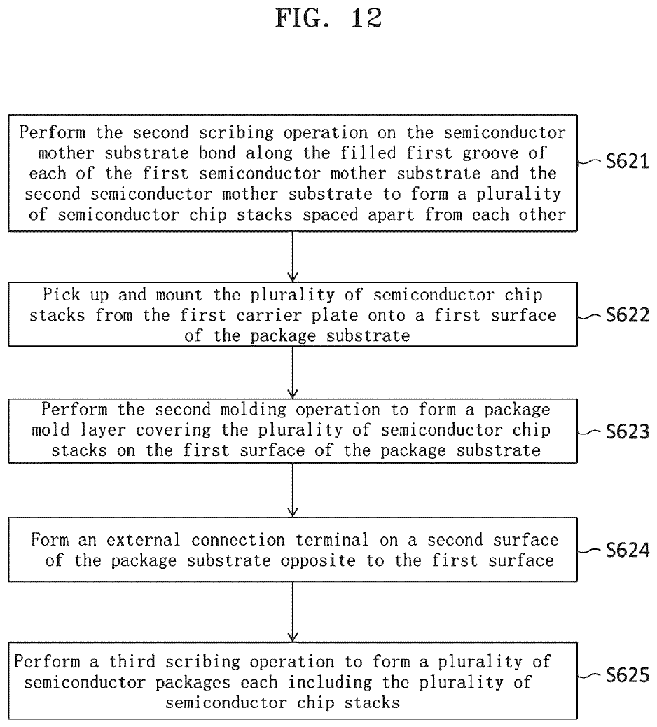

FIG. 10 is a flowchart illustrating the method of manufacturing the semiconductor chip according to an example embodiment of the present disclosure. FIG. 11 is a process diagram illustrating the methods of FIGS. 10 and 12 according to example embodiments of the present disclosure.

Referring to FIGS. 10 and 11 together with FIGS. 6 and 7A-7C, in one example embodiment, after the step S500 shown in FIG. 6, steps S810-S830 may be performed.

In step S810 and process I-7, the thinning operation may be performed on the semiconductor mother substrate to expose the plurality of through mold vias, to thereby obtain a first semiconductor mother substrate. In step S820 and process II-8, a second semiconductor mother substrate that is identical to the first semiconductor mother substrate is vertically stacked on the first semiconductor mother substrate such that the first semiconductor mother substrate and the second semiconductor mother substrate may be electrically connected to each other through corresponding through mold vias to form a semiconductor mother substrate bond. In step S830 and process II-9, the semiconductor mother substrate bond may be disposed on the first carrier plate P1.

FIG. 12 is a flowchart illustrating the method of manufacturing the package of the semiconductor chip according to an example embodiment of the present disclosure.

Referring to FIGS. 10 and 12 together with FIG. 11, in one example embodiment, after the step S830 shown in FIG. 10, the step S600 may be performed. In this case, the step S600 may include steps S621-S625.

In step S621 and process II-9, the second scribing operation may be performed on the semiconductor mother substrate bond along the filled first groove T1 of each of the first semiconductor mother substrate and the second semiconductor mother substrate to form the plurality of semiconductor chip stacks STK spaced apart from each other. In step S622 and process II-10, the plurality of semiconductor chip stacks STK may be picked up from the first carrier plate P1 and mounted onto the first surface of the package substrate. In step S623 and process II-10, the second molding operation may be performed to form the package mold layer covering the plurality of semiconductor chip stacks STK on the first surface of the package substrate. In step S624 and process II-10, the external connection terminal may be formed on the second surface of the package substrate opposite to the first surface. In step S625 and process II-10, a third scribing operation may be performed to form the plurality of semiconductor packages each including the plurality of semiconductor chip stacks STK.

In one example, each of the plurality of semiconductor packages including the plurality of semiconductor chip stacks STK manufactured according to the flow chart of FIG. 12 may include, for example, the semiconductor package 100 shown in FIG. 3. According to the example embodiment of the present disclosure, because the chip redistribution layer of the semiconductor chip is electrically connected to the through mold via extending along the outer side surface of the scribe lane and the side surface of the chip substrate, and is electrically connected to an external device through the package substrate 110, electrical connection between the semiconductor chip and the external device can be implemented at a side surface of the semiconductor chip, so that a thickness of the semiconductor package may be reduced, and bandwidths and the number of IO of the semiconductor chip also may be increased to improve performance.

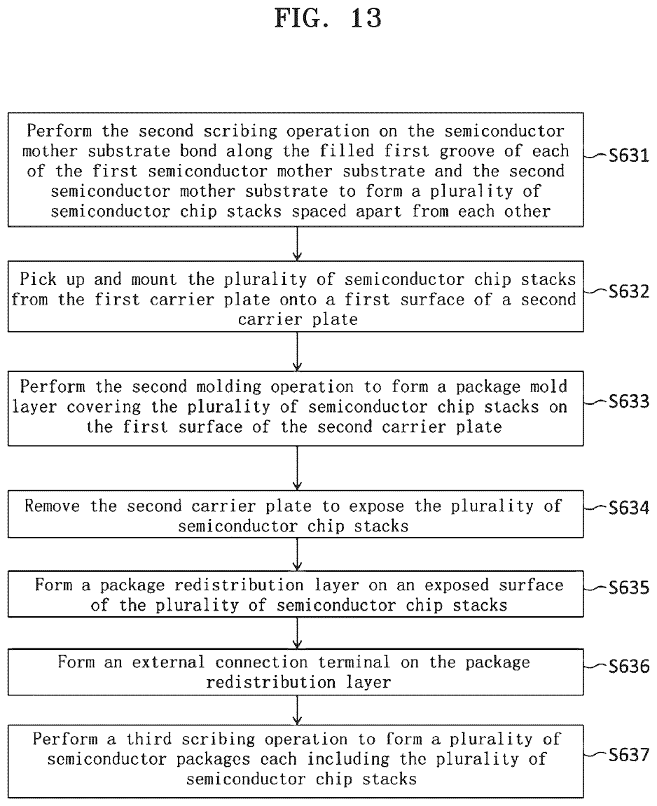

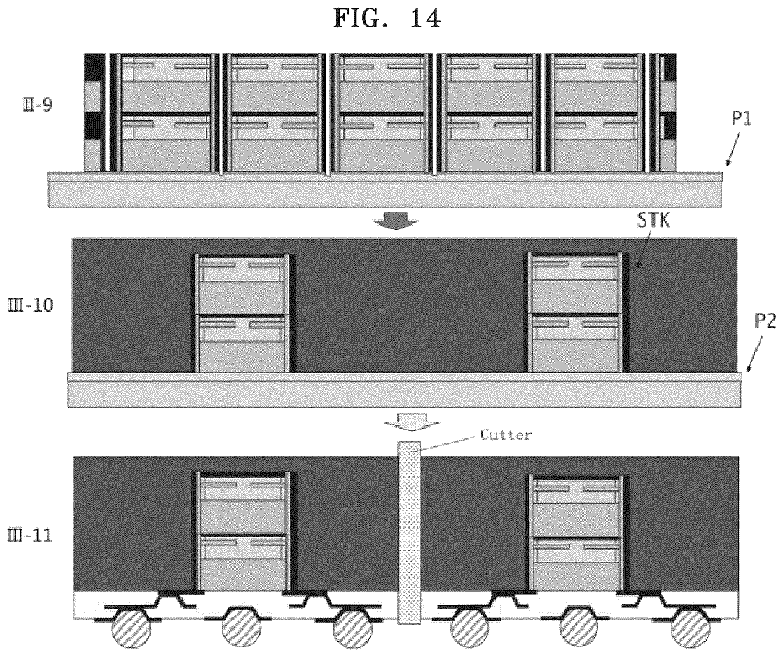

FIG. 13 is a flowchart illustrating the method of manufacturing the package of the semiconductor chip according to an example embodiment of the present disclosure. FIG. 14 is a process diagram illustrating the method of FIG. 13 according to the present disclosure.

Referring to FIGS. 13 and 14 together with FIGS. 10 and 11, in one example embodiment, after the step S830 shown in FIG. 10, the step S600 may be performed. In this case, the step S600 may include steps S631-S637.

In step S631 and process II-9, the second scribing operation may be performed on the semiconductor mother substrate bond along the filled first groove T1 of each of the first semiconductor mother substrate and the second semiconductor mother substrate to form the plurality of semiconductor chip stacks STK spaced apart from each other. In step S632 and process III-10, the plurality of semiconductor chip stacks STK may be picked up from the first carrier plate P1 and mounted onto the first surface of the second carrier plate P2. In step S633 and process III-10, the second molding operation may be performed to form the package mold layer covering the plurality of semiconductor chip stacks STK on the first surface of the second carrier plate P2. In step S634 and process III-11, the second carrier plate P2 may be removed to expose the plurality of semiconductor chip stacks STK. In step S635 and process III-11, a package redistribution layer may be formed on an exposed surface of the plurality of semiconductor chip stacks STK. In step S636, the external connection terminal may be formed on the package redistribution layer. In step S637 and process III-11, a third scribing operation may be performed to form the plurality of semiconductor packages each including the plurality of semiconductor chip stacks STK.

In one example, each of the plurality of semiconductor packages including the plurality of semiconductor chip stacks STK manufactured according to the flow chart of FIG. 13 may include, for example, the semiconductor package 200 shown in FIG. 4. According to the example embodiment of the present disclosure, because the chip redistribution layer of the semiconductor chip is electrically connected to the through mold via extending along the outer side surface of the scribe lane and the side surface of the chip substrate, and is electrically connected to an external device through the package redistribution layer, electrical connection between the semiconductor chip and the external device can be implemented at a side surface of the semiconductor chip, so that a thickness of the semiconductor package may be reduced, and bandwidths and the number of IO of the semiconductor chip also may be increased to improve performance.

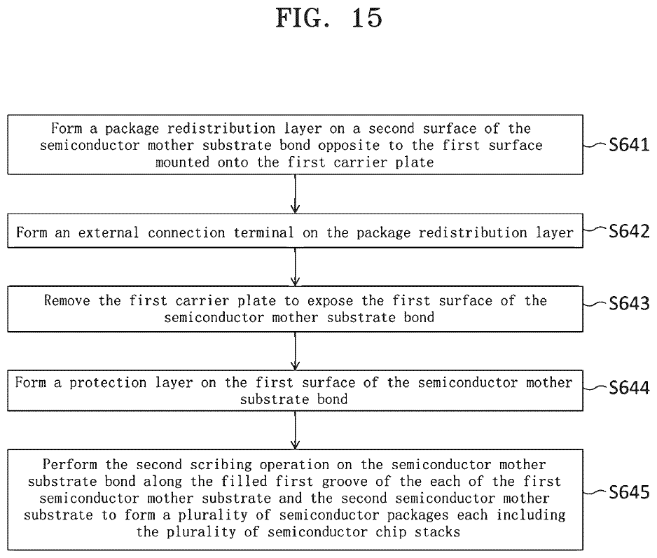

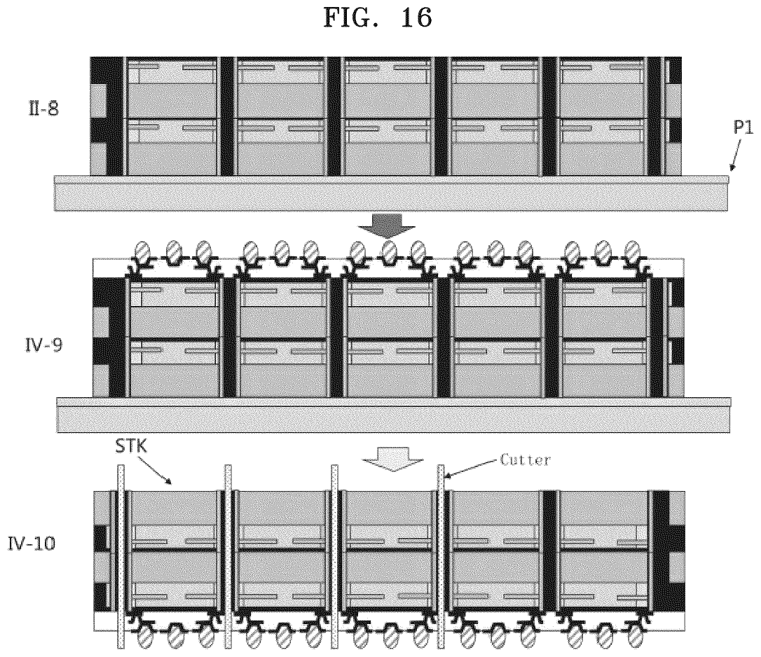

FIG. 15 is a flowchart illustrating the methods of manufacturing the semiconductor chip and the package thereof according to an example embodiment of the present disclosure. FIG. 16 is a process diagram illustrating the method of manufacturing the semiconductor chip according to an example embodiment of the present disclosure.

Referring to FIGS. 15 and 16 together with FIGS. 7A-7C and 9, in one example embodiment, after the step S830 shown in FIG. 9, the step S600 may be performed. In this case, the step S600 may include steps S641-S645.

In step S641 and process IV-9, the package redistribution layer may be formed on a second surface of the semiconductor mother substrate bond opposite to the first surface mounted onto the first carrier plate P1. In step S642 and process IV-9, the external connection terminal may be formed on the package redistribution layer. In step S643 and process IV-10, the first carrier plate P1 may be removed to expose the first surface of the semiconductor mother substrate bond. In step S644 and process IV-10, a protection layer may be formed on the first surface of the semiconductor mother substrate bond. In step S645 and process IV-10, the second scribing operation may be performed on the semiconductor mother substrate bond along the filled first groove T1 of each of the first semiconductor mother substrate and the second semiconductor mother substrate to form the plurality of semiconductor packages each including the plurality of semiconductor chip stacks STK.

In one example, each of the plurality of semiconductor packages including the plurality of semiconductor chip stacks STK manufactured according to the flow chart of FIG. 15 may include, for example, the semiconductor package 300 shown in FIG. 5. According to the example embodiment of the present disclosure, because the chip redistribution layer of the semiconductor chip is electrically connected to the through mold via extending along the outer side surface of the scribe lane and the side surface of the chip substrate, and is electrically connected to an external device through the package redistribution layer, electrical connection between the semiconductor chip and the external device can be implemented at a side surface of the semiconductor chip, so that a thickness of the semiconductor package may be reduced, and bandwidths and the number of IO of the semiconductor chip also may be increased to improve performance.

In the semiconductor chips according to the example embodiments of the present disclosure, because the chip redistribution layer is exposed to the outside of the scribe lane and an outer side surface of the scribe lane is coplanar with a side surface of the chip substrate, electrical connection between the semiconductor chip and an external device can be realized at a side surface of the semiconductor chip, so that a thickness of a package including the semiconductor chip may be reduced, and bandwidths and the number of IO of the semiconductor chip also may be increased to improve performance.

The present disclosure has been particularly shown and described with reference to some example embodiments thereof, it shall be understood by those skilled in the art that various changes in form and details may be made therein without departing from the spirit and scope of the present disclosure as defined by the claims.

1. A semiconductor chip, including:
a chip substrate;
a pattern on an upper surface of the chip substrate;
a scribe lane on the upper surface of the chip substrate and surrounding the pattern; and
a chip redistribution layer in the pattern, the chip redistribution layer extending from the pattern into the scribe lane, passing through the scribe lane, and exposed to an outside of the scribe lane.

2. The semiconductor chip of claim 1, wherein
the pattern covers a portion of the upper surface of the chip substrate, and
the scribe lane covers a remaining portion of the upper surface of the chip substrate.

3. The semiconductor chip of claim 1, wherein
an inner side surface of the scribe lane contacts the pattern, and
an outer side surface of the scribe lane is coplanar with a side surface of the chip substrate.

4. The semiconductor chip of claim 1, wherein
the chip redistribution layer extends from the pattern into the scribe lane in a direction parallel to the upper surface of the chip substrate.

5. The semiconductor chip of claim 1, wherein
an exposed surface of the chip redistribution layer exposed to the outside of the scribe lane is coplanar with an outer side surface of the scribe lane.

6. The semiconductor chip of claim 5, wherein
the semiconductor chip is included in a semiconductor package.

7. The semiconductor chip of claim 6, further including:
a through mold via extending along the outer side surface of the scribe lane and a side surface of the chip substrate and electrically connected to the exposed surface of the chip redistribution layer.

8. The semiconductor chip of claim 7, further including:
a chip mold layer covering an upper surface of the pattern, an upper surface of the scribe lane and an outer side surface of the through mold via,
wherein the through mold via passes through the chip mold layer to be exposed to an outside of both a first surface as an active surface and a second surface, the second surface of the semiconductor chip being opposite to the first surface of the semiconductor chip.

9. The semiconductor chip of claim 8, wherein the semiconductor package includes:
a package substrate including a first surface and a second surface opposite to the first surface, wherein an active surface of the semiconductor chip faces upward on the first surface of the package substrate, and the chip redistribution layer of the semiconductor chip is being electrically connected to the package substrate through the through mold via;
a package mold layer on the first surface of the package substrate and covering the semiconductor chip; and
an external connection terminal on the second surface of the package substrate.

10. The semiconductor chip of claim 8, wherein the semiconductor package includes:
a package redistribution layer including a first surface and a second surface opposite to the first surface, wherein an active surface of the semiconductor chip faces upward on the first surface of the package redistribution layer, and the chip redistribution layer of the semiconductor chip is electrically connected to the package redistribution layer through the through mold via;
a package mold layer on the first surface of the package redistribution layer and covering the semiconductor chip; and
an external connection terminal on the second surface of the package redistribution layer.

11. The semiconductor chip of claim 8, wherein the semiconductor package includes:
a package redistribution layer including a first surface and a second surface opposite to the first surface, wherein an active surface of the semiconductor chip faces downward on the first surface of the package redistribution layer, and the chip redistribution layer of the semiconductor chip is electrically connected to the package redistribution layer through the through mold via; and
an external connection terminal on the second surface of the package redistribution layer.

12. The semiconductor chip of claim 7, wherein
the semiconductor chip is a first semiconductor chip,
the semiconductor package further includes:
a second semiconductor chip vertically stacked on the first semiconductor chip, the first semiconductor chip and the second semiconductor chip electrically connected to each other through the through mold via.

13. A method of manufacturing a semiconductor chip, including:
forming a plurality of patterns, a plurality of scribe lanes, and a plurality of chip redistribution layers on a semiconductor mother substrate such that the plurality of patterns are spaced apart by the plurality of scribe lanes, and the plurality of chip redistribution layers extend from corresponding ones of the plurality of patterns into corresponding ones of the plurality of scribe lanes, respectively;
performing a first scribing operation on the semiconductor mother substrate along the plurality of scribe lanes to form a first groove in each of the plurality of scribe lanes, the first groove extending into the semiconductor mother substrate and having a first depth and a first width such that each of the plurality of chip redistribution layers is exposed through the first groove;
performing a first molding operation to form a chip mold layer filling the first groove;
forming holes through the chip mold layer along an inner side surface of the filled first groove to expose each of the plurality of chip redistribution layers through the holes;
filling the holes with a conductive material to form a plurality of through mold vias that is electrically connected to the plurality of chip redistribution layers, respectively; and
performing a second scribing operation on the semiconductor mother substrate along the filled first groove to form a plurality of semiconductor chips each including the plurality of patterns.

14. The method of claim 13, wherein
the plurality of scribe lanes include a plurality of first scribe lanes extending in a first direction and a plurality of second scribe lanes extending in a second direction intersecting the first direction.

15. The method of claim 14, wherein
each of the plurality of patterns is spaced apart from adjacent ones of the plurality of patterns through two of the plurality of first scribe lanes and two of the plurality of second scribe lanes.

16. The method of claim 14, wherein
the plurality of chip redistribution layers include
a plurality of first chip redistribution layers each extending from a corresponding one of the plurality of patterns into a corresponding one of the plurality of first scribe lanes, and
a plurality of second chip redistribution layers each extending from a corresponding one of the plurality of patterns into a corresponding one of the plurality of second scribe lanes.

17. The method of claim 13, wherein
the first depth is greater than a depth of each of the plurality of scribe lanes, and the first width is less than a width of each of the plurality of scribe lanes.

18. The method of claim 13, wherein
each of the plurality of patterns is spaced apart from the first groove by a portion that is not scribed in each of the plurality of scribe lanes.

19. The method of claim 13, wherein the performing the first molding operation further includes:
forming the chip mold layer to cover upper surfaces of the plurality of patterns and upper surfaces of portions that are not scribed in the plurality of scribe lanes.

20. The method of claim 13, wherein
the forming the holes includes forming the holes on opposite inner side surfaces of the first groove in a cross-sectional view and expose the chip redistribution layers facing each other across the first groove, respectively.

21-29. (canceled)
